(19) United States
(12) Patent Application Publication
(10) Pub. No.: US 2026/0098149 A1
(43) Pub. Date: Apr. 9, 2026

(54) RESIN COMPOSITION FOR MOLDING AND ELECTRONIC COMPONENT DEVICE

(71) Applicant: RESONAC CORPORATION, Tokyo (JP)

(72) Inventors: Mika TANAKA, Minato-ku, Tokyo (JP); Yuma TAKEUCHI, Minato-ku, Tokyo (JP); Yuta SUKEGAWA, Minato-ku, Tokyo (JP); Shintaro OKADA, Minato-ku, Tokyo (JP)

(73) Assignee: RESONAC CORPORATION, Tokyo (JP)

(21) Appl. No.: 18/861,581

(22) PCT Filed: Nov. 13, 2023
(86) PCT No.: PCT/JP2023/040829

§ 371 Date: Oct. 30, 2024

(30) Foreign Application Priority Data
Nov. 25, 2022 (JP) 2022-188706

(51) Int. Cl. C08L 63/04; C08G 59/58; C08K 3/04; C08K 5/49; C08K 5/5435; C08K 5/544; C08K 7/22; H01Q 1/40; H10W 74/47

(52) U.S. Cl. CPC C08L 63/04; C08G 59/58; C08K 3/04; C08K 5/49; C08K 5/5435; C08K 5/544; C08K 7/22; H10W 74/473; C08L 2203/206; C08L 2207/53; H01Q 1/40

(57) ABSTRACT

A resin composition for molding includes an epoxy resin, a curing agent containing an active ester compound, an inorganic filler, and a porous polymer particle.

### TECHNICAL FIELD

The disclosure relates to a resin composition for molding and an electronic component device.

### RELATED ART

In response to demands for advancement in functionality and miniaturization of electronic devices in recent years, high-density integration, and further, high-density mounting, of electronic components have been progressing, and semiconductor packages used in such electronic devices are increasing and becoming smaller than ever before. Furthermore, radio waves used for communication in electronic devices are also becoming higher in frequency.

For example, in Patent Document 1 and Patent Document 2, resin compositions with high dielectric constants used for sealing semiconductor elements have been proposed from the viewpoint of accommodating miniaturization and high frequency of semiconductor packages.

### RELATED ART DOCUMENTS

### Patent Documents

Patent Document 1: Japanese Patent Application Laid-Open No. 2015-036410
Patent Document 2: Japanese Patent Application Laid-Open No. 2018-141052

### SUMMARY OF INVENTION

### Problem to be Solved by Invention

Examples of a material for sealing electronic components such as semiconductor elements include a resin composition for molding including an epoxy resin, a curing agent, and an inorganic filler. With a material of a high dielectric loss tangent used as the above resin composition for molding, a transmission signal is converted to heat due to dielectric loss, and communication efficiency tends to decrease. Herein, an amount of dielectric loss generated due to heat conversion of radio waves emitted for communication in a dielectric is expressed as a product of a frequency, a square root of a relative permittivity, and a dielectric loss tangent. The transmission signal becomes easily converted to heat in proportion to the frequency. Particularly in recent years, to accommodate an increase in the number of channels and the like accompanying diversification of information, the radio waves used for communication have become higher in frequency. To suppress dielectric loss, a resin composition for molding capable of molding a cured product with a low relative permittivity is required.

The disclosure has been made in view of the above conventional circumstances, and an objective thereof is to provide a resin composition for molding capable of molding a cured product with a low relative permittivity, and an electronic component device using the same.

### Means for Solving Problem

Specific means for achieving the above objective are as follows.
<1> A resin composition for molding including: an epoxy resin, a curing agent containing an active ester compound, an inorganic filler, and a porous polymer particle.
<2> The resin composition for molding according to <1>, in which the porous polymer particle includes a core part having a porous structure and a shell part covering at least a part of the core part.
<3> The resin composition for molding according to <1> or <2>, in which the porous polymer particle includes a core part having a porous structure, and the core part includes at least one polymer selected from a group consisting of (meth)acrylic polymers, olefin polymers, styrene polymers, and urethane polymers.
<4> The resin composition for molding according to any one of <1> to <3>, in which a content ratio of the porous polymer particle is 5 volume % to 50 volume % with respect to a total amount of the inorganic filler and the porous polymer particle.
<5> The resin composition for molding according to any one of <1> to <4>, in which a content ratio of the porous polymer particle is 3 volume % to 40 volume % with respect to a total amount of the resin composition for molding.
<6> The resin composition for molding according to any one of <1> to <5>, in which the porous polymer particle has thermosetting properties.
<7> The resin composition for molding according to any one of <1> to <6>, which is used for a high-frequency device.
<8> The resin composition for molding according to <7>, which is used for sealing an electronic component in the high-frequency device.
<9> The resin composition for molding according to <7>, which is used for an Antenna-in-Package.
<10> An electronic component device including:
a supporting member;
an electronic component disposed on the supporting member; and
a cured product of the resin composition for molding according to any one of <1> to <9>, which seals the electronic component.
<11> The electronic component device according to <10>, in which the electronic component includes an antenna.

### Effects of Invention

According to the disclosure, it is possible to provide a resin composition for molding capable of molding a cured product with a low relative permittivity, and an electronic component device using the same.

### BRIEF DESCRIPTION OF DRAWINGS

FIG. 1 is a graph showing an S-S curve of an elongation at break and a flexural strength obtained using a resin composition for molding of each Example and each Comparative Example.

FIG. 2 is a graph showing changes in viscoelastic properties obtained using a composition including a filler 5.

### DESCRIPTION OF EMBODIMENTS

Hereinafter, embodiments of the disclosure will be described in detail. However, the disclosure is not limited to the following embodiments. In the following embodiments, constituent elements thereof (including element steps and the like) are not necessarily required unless explicitly stated. The same applies to numerical values and ranges thereof, which do not limit the disclosure.

In the disclosure, the term “process” includes not only a process that is independent of other processes, but also a process that cannot be clearly distinguished from other processes as long as the purpose of the process is achieved.

In the disclosure, a numerical range indicated using “A to B” includes numerical values described before and after “to” as a minimum value and a maximum value, respectively.

In numerical ranges described in stages in the disclosure, an upper limit value or a lower limit value described in one numerical range may be replaced with an upper limit value or a lower limit value of another numerical range described in stages. Further, in the numerical ranges described in the disclosure, the upper limit value or the lower limit value of the numerical range may be replaced with a value shown in Examples.

In the disclosure, each component may include multiple types of corresponding substances. In the case where multiple types of substances corresponding to each component are present in a composition, unless otherwise specified, a content ratio or a content of each component refers to a total content ratio or content of the multiple types of substances present in the composition.

In the disclosure, a particle corresponding to each component may include multiple types of particles. In the case where multiple types of particles corresponding to each component are present in a composition, unless otherwise specified, a particle diameter of each component refers to a value for a mixture of the multiple types of particles present in the composition.

### <Resin Composition for Molding>

A resin composition for molding of the disclosure includes an epoxy resin, a curing agent containing an active ester compound, an inorganic filler, and a porous polymer particle. Accordingly, the resin composition for molding of the disclosure is capable of molding a cured product having a low relative permittivity.

Hereinafter, each component constituting the resin composition for molding will be described. The resin composition for molding of the disclosure includes at least an epoxy resin, a curing agent, an inorganic filler, and a porous polymer particle, and may also include other components as necessary.

### (Epoxy Resin)

The resin composition for molding of the disclosure includes an epoxy resin. A type of the epoxy resin is not particularly limited as long as the epoxy resin includes an epoxy group in a molecule.

From the viewpoint of strength, flowability, heat resistance, moldability, etc., a mass ratio of the epoxy resin in an entirety of the resin composition for molding is preferably 0.5 mass % to 30 mass %, more preferably 2 mass % to 20 mass %, and even more preferably 3.5 mass % to 13 mass %.

Examples of the epoxy resin includes: novolac type epoxy resins (phenol novolac type epoxy resin, o-cresol novolac type epoxy resin, etc.) obtained by epoxidizing novolac resins produced by condensation or co-condensation, under acidic catalysis, of at least one phenolic compound selected from the group consisting of phenol compounds such as phenol, cresol, xylenol, resorcinol, catechol, bisphenol A, bisphenol F, etc., and naphthol compounds such as α-naphthol, β-naphthol, dihydroxynaphthalene, etc., with aliphatic aldehyde compounds such as formaldehyde, acetaldehyde, propionaldehyde, etc.; triphenylmethane type epoxy resins obtained by epoxidizing triphenylmethane type phenol resins produced by condensation or co-condensation, under acidic catalysis, of the above phenolic compounds with aromatic aldehyde compounds such as benzaldehyde, salicylaldehyde, etc.; copolymer type epoxy resins obtained by epoxidizing novolac resins produced by co-condensation, under acidic catalysis, of the above phenol compounds and naphthol compounds with aldehyde compounds; diphenylmethane type epoxy resins which are diglycidyl ethers of bisphenol A, bisphenol F, etc.; biphenyl type epoxy resins which are diglycidyl ethers of alkyl-substituted or unsubstituted biphenols; stilbene type epoxy resins which are diglycidyl ethers of stilbene-based phenol compounds; epoxy resins which are glycidyl ethers of alcohols such as butanediol, polyethylene glycol, polypropylene glycol, etc.; glycidyl ester type epoxy resins which are glycidyl esters of polyvalent carboxylic acid compounds such as phthalic acid, isophthalic acid, tetrahydrophthalic acid, etc.; glycidylamine type epoxy resins in which active hydrogen bonded to nitrogen atoms of aniline, diaminodiphenylmethane, isocyanuric acid, etc. is replaced with glycidyl groups; dicyclopentadiene type epoxy resins obtained by epoxidizing co-condensation resins of dicyclopentadiene and phenol compounds; alicyclic epoxy resins such as vinylcyclohexene diepoxide, 3,4-epoxycyclohexylmethyl-3,4-epoxycyclohexanecarboxylate, 2-(3,4-epoxy)cyclohexyl-5,5-spiro(3,4-epoxy)cyclohexane-m-dioxane, etc., in which olefin bonds in the molecule are epoxidized; paraxylylene-modified epoxy resins which are glycidyl ethers of paraxylylene-modified phenol resins; metaxylylene-modified epoxy resins which are glycidyl ethers of metaxylylene-modified phenol resins; terpene-modified epoxy resins which are glycidyl ethers of terpene-modified phenol resins; dicyclopentadiene-modified epoxy resins which are glycidyl ethers of dicyclopentadiene-modified phenol resins; cyclopentadiene-modified epoxy resins which are glycidyl ethers of cyclopentadiene-modified phenol resins; polycyclic aromatic ring-modified epoxy resins which are glycidyl ethers of polycyclic aromatic ring-modified phenol resins; naphthalene type epoxy resins which are glycidyl ethers of naphthalene ring-containing phenol resins; halogenated phenol novolac type epoxy resins; hydroquinone type epoxy resins; trimethylolpropane type epoxy resins; linear aliphatic epoxy resins obtained by oxidizing olefin bonds with peracids such as peracetic acid; aralkyl type epoxy resins obtained by epoxidizing aralkyl type phenol resins such as phenol aralkyl resins, naphthol aralkyl resins, etc. Furthermore, examples of the epoxy resin include epoxidized acrylic resins and the like. The epoxy resin may be used as one type alone or used as a combination of two or more types.

The epoxy resin may include at least one of triphenylmethane type epoxy resin, o-cresol novolac type epoxy resin, biphenyl aralkyl type epoxy resin, and biphenyl type epoxy resin. The epoxy resin may also include triphenylmethane type epoxy resin and biphenyl type epoxy resin, or triphenylmethane type epoxy resin and o-cresol novolac type epoxy resin.

An epoxy equivalent (molecular weight/number of epoxy groups) of the epoxy resin is not particularly limited. From the viewpoint of balancing various properties such as moldability, reflow resistance, electrical reliability, etc., the epoxy equivalent of the epoxy resin is preferably 100 g/eq to 1000 g/eq, and more preferably 150 g/eq to 500 g/eq.

The epoxy equivalent of the epoxy resin is a value measured according to a method conforming to JIS K 7236:2009.

In the case where the epoxy resin is solid, a softening point or a melting point of the epoxy resin is not particularly limited. The softening point or the melting point of the epoxy resin is preferably 40° C. to 180° C. from the viewpoint of moldability and reflow resistance, and is more preferably 50° C. to 130° C. from the viewpoint of handling during preparation of the resin composition for molding.

The melting point or the softening point of the epoxy resin is a value measured according to differential scanning calorimetry (DSC) or according to a method (ring and ball method) conforming to JIS K 7234:1986.

### (Curing Agent)

The resin composition for molding of the disclosure includes a curing agent containing an active ester compound.

The resin composition for molding may include only one type of curing agent, or may include two or more types of curing agent. For example, the curing agent may include one type of active ester compound, may include two or more types of active ester compound, or may include an active ester compound and another curing agent (e.g., phenol curing agent).

In the case where a phenol curing agent, for example, is used as the curing agent of the epoxy resin, secondary hydroxyl groups are generated in the reaction between the epoxy resin and the phenol curing agent. In contrast, in the case where an active ester compound is used as the curing agent of the epoxy resin, ester groups are formed instead of secondary hydroxyl groups in the reaction between the epoxy resin and the active ester compound. Since ester groups have a lower polarity compared to secondary hydroxyl groups, it is inferred that a resin composition for molding including an active ester compound as a curing agent can suppress the dielectric loss tangent and the relative permittivity of the cured product to lower levels compared to a resin composition for molding including only a curing agent that generates secondary hydroxyl groups as the curing agent.

Further, polar groups in the cured product increase water absorption of the cured product. By using an active ester compound as the curing agent, a concentration of polar groups in the cured product can be suppressed, and water absorption of the cured product can be suppressed. It is inferred that by suppressing water absorption of the cured product, i.e., by suppressing a content of H₂O, which is a polar molecule, the dielectric loss tangent and the relative permittivity of the cured product can be further suppressed to lower levels.

### —Active Ester Compound—

Herein, the active ester compound refers to a compound that includes, in one molecule, one or more ester groups that react with epoxy groups, and has an effect of curing the epoxy resin.

A type of the active ester compound is not particularly limited as long as the active ester compound is a compound that includes, in the molecule, one or more ester groups that react with epoxy groups. Examples of the active ester compound include phenol ester compounds, thiophenol ester compounds, N-hydroxyamine ester compounds, esterified heterocyclic hydroxy compounds, etc. These active ester compounds may be used as one type alone or used as a combination of two or more types.

Examples of the active ester compound include, for example, ester compounds obtained from at least one of aliphatic carboxylic acids and aromatic carboxylic acids, and at least one of aliphatic hydroxy compounds and aromatic hydroxy compounds. Ester compounds that take aliphatic compounds as components of polycondensation tend to be excellent in compatibility with epoxy resins due to the aliphatic chains included. Ester compounds that take aromatic compounds as components of polycondensation tend to be excellent in heat resistance due to the aromatic rings included.

Specific examples of the active ester compound include aromatic esters obtained by condensation reactions between aromatic carboxylic acids and phenolic hydroxyl groups. Specifically, aromatic esters obtained by condensation reactions between aromatic carboxylic acids and phenolic hydroxyl groups are preferable, taking a mixture of the following as raw materials: an aromatic carboxylic acid component in which 2 to 4 hydrogen atoms of aromatic rings such as benzene, naphthalene, biphenyl, diphenylpropane, diphenylmethane, diphenyl ether, diphenylsulfonic acid, etc. are replaced with carboxyl groups; a monovalent phenol in which 1 hydrogen atom of the above aromatic ring is replaced with a hydroxyl group; and a polyvalent phenol in which 2 to 4 hydrogen atoms of the above aromatic ring are replaced with hydroxyl groups. In other words, aromatic esters including structural units derived from the above aromatic carboxylic acid component, structural units derived from the above monovalent phenol, and structural units derived from the above polyvalent phenol are preferable.

Specific examples of the active ester compound include active ester resins having a structure obtained by reacting a phenolic resin having a molecular structure in which phenol compounds are linked via an alicyclic hydrocarbon group, an aromatic dicarboxylic acid or a halide thereof, and an aromatic monohydroxy compound, as described in Japanese Patent Application Laid-Open No. 2012-246367. As such active ester resins, compounds represented by Structural Formula (1) below are preferable.

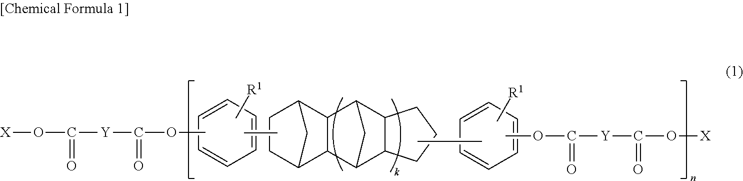

In Structural Formula (1), R¹ is a hydrogen atom, an alkyl group having 1 to 4 carbon atoms, or a phenyl group; X is an unsubstituted benzene ring, an unsubstituted naphthalene ring, a benzene ring or a naphthalene ring replaced with an alkyl group having 1 to 4 carbon atoms, or a biphenyl group; Y is a benzene ring, a naphthalene ring, or a benzene ring or a naphthalene ring replaced with an alkyl group having 1 to 4 carbon atoms; k is 0 or 1; and n represents an average number of repetitions and is 0 to 5.

Specific examples of compounds represented by Structural Formula (1) include Exemplary Compounds (1-1) to (1-10) below. In the structural formulas, t-Bu represents a tert-butyl group.

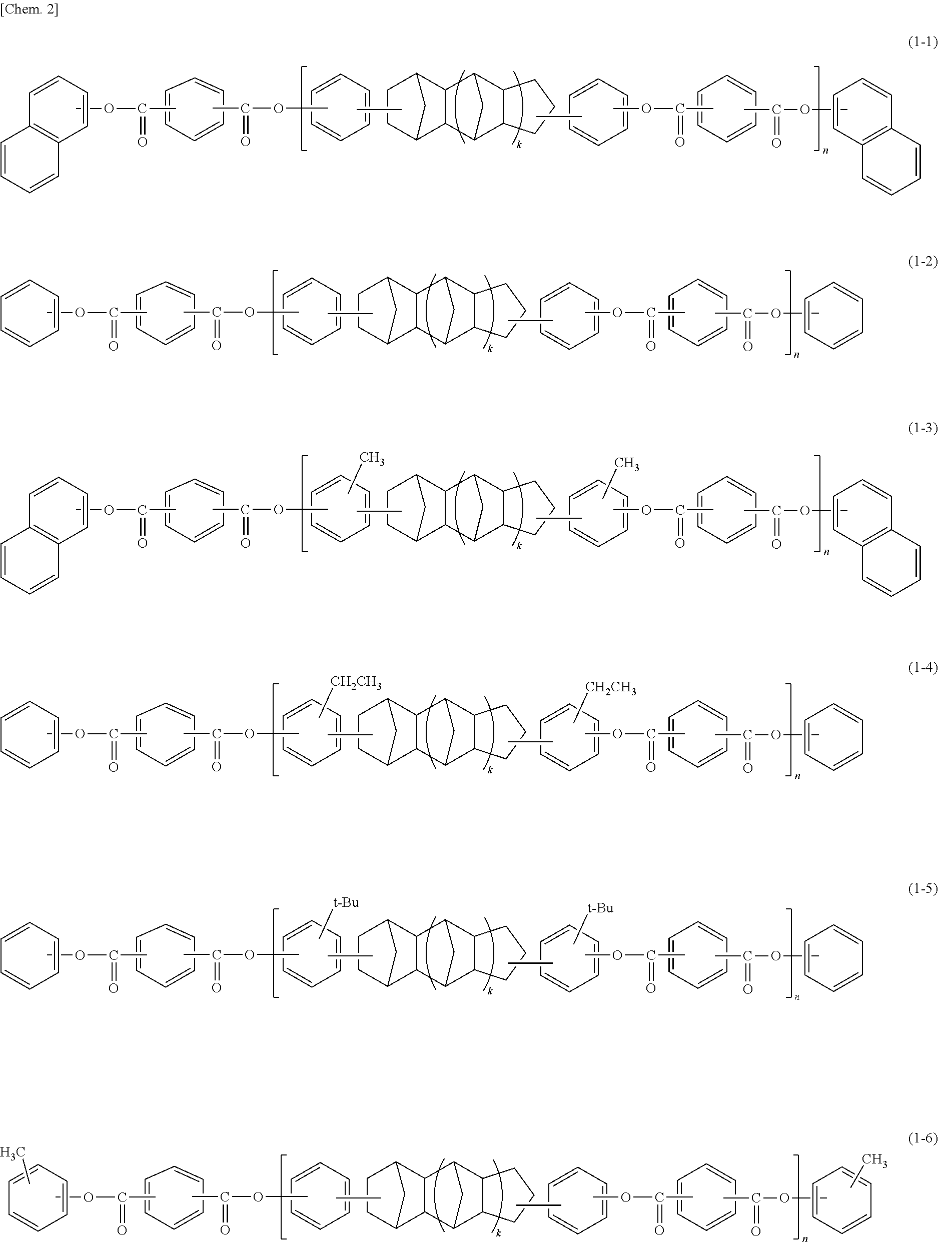

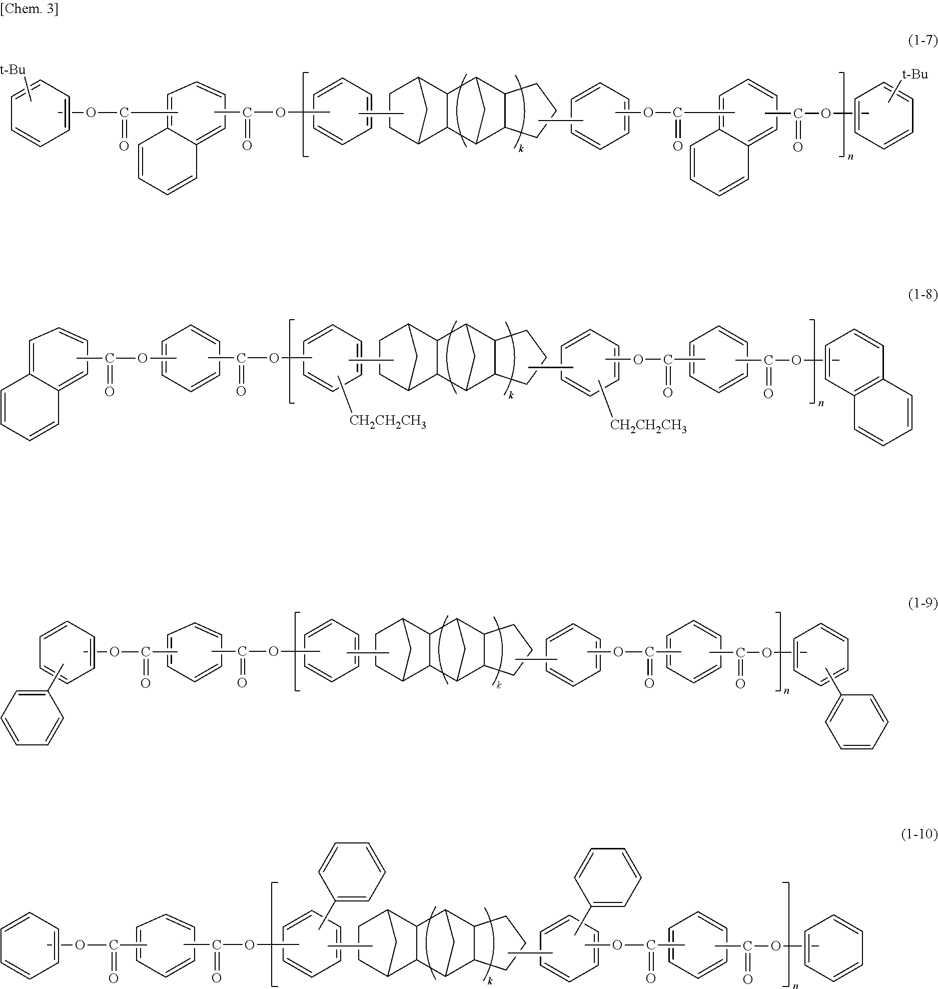

Other specific examples of the active ester compound include compounds represented by Structural Formula (2) below and compounds represented by Structural Formula (3) below, as described in Japanese Patent Application Laid-Open No. 2014-114352.

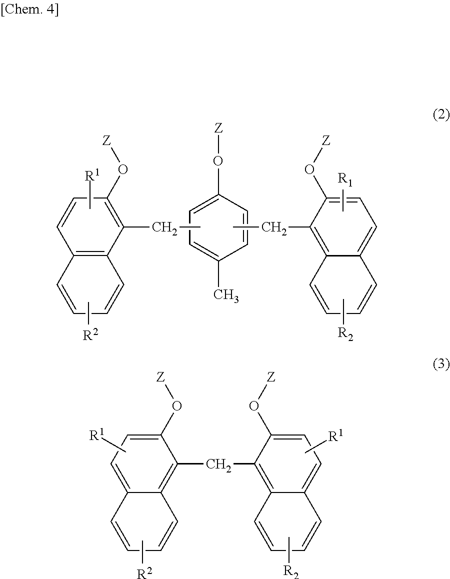

In Structural Formula (2), R¹ and R² are each independently a hydrogen atom, an alkyl group having 1 to 4 carbon atoms, or an alkoxy group having 1 to 4 carbon atoms; Z is an ester-forming structural moiety (z1) selected from the group consisting of an unsubstituted benzoyl group, an unsubstituted naphthoyl group, a benzoyl group or a naphthoyl group replaced with an alkyl group having 1 to 4 carbon atoms, and an acyl group having 2 to 6 carbon atoms, or a hydrogen atom (z2); and at least one Z is the ester-forming structural moiety (z1).

In Structural Formula (3), R¹ and R² are each independently a hydrogen atom, an alkyl group having 1 to 4 carbon atoms, or an alkoxy group having 1 to 4 carbon atoms; Z is an ester-forming structural moiety (z1) selected from the group consisting of an unsubstituted benzoyl group, an unsubstituted naphthoyl group, a benzoyl group or a naphthoyl group replaced with an alkyl group having 1 to 4 carbon atoms, and an acyl group having 2 to 6 carbon atoms, or a hydrogen atom (z2); and at least one Z is the ester-forming structural moiety (z1).

Specific examples of compounds represented by Structural Formula (2) include Exemplary Compounds (2-1) to (2-6) below.

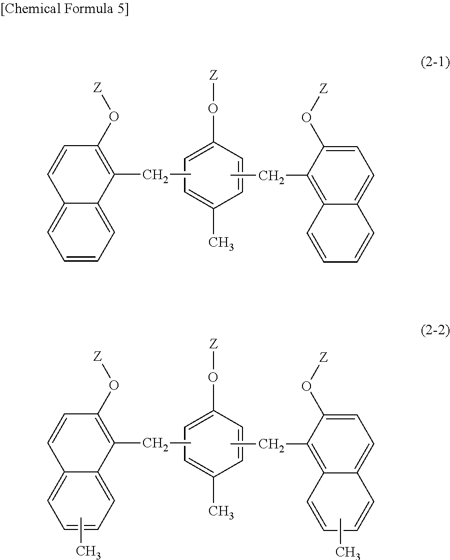

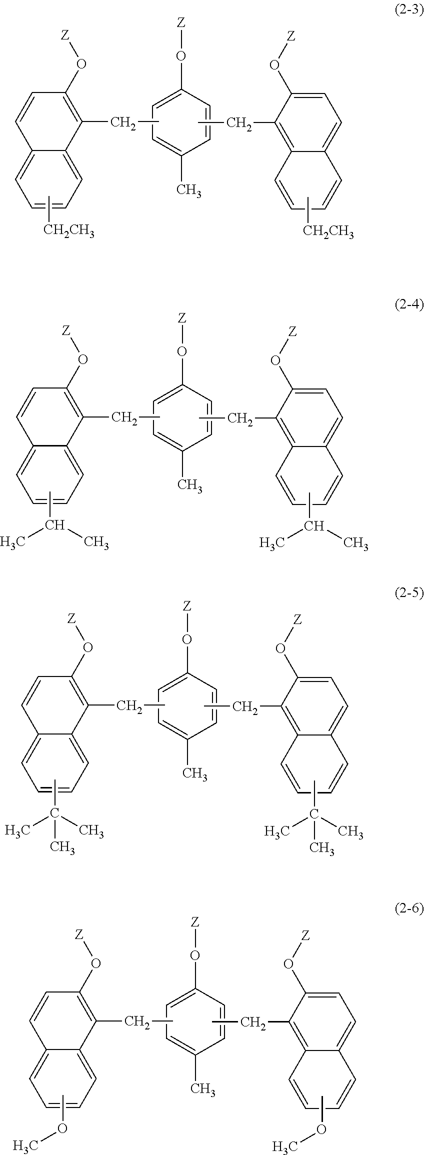

Specific examples of compounds represented by Structural Formula (3) include Exemplary Compounds (3-1) to (3-6) below.

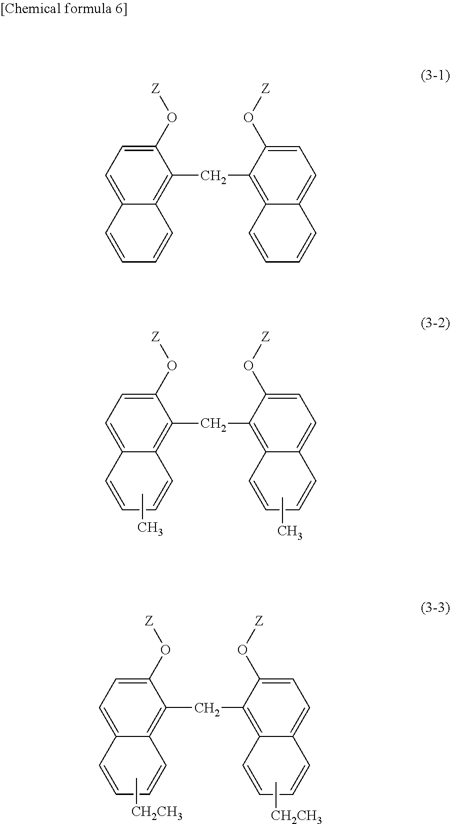

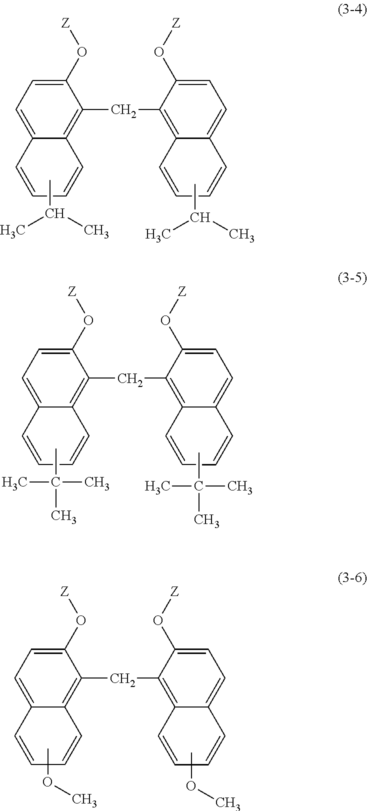

Commercially available products may be used as the active ester compound. Examples of commercially available products of the active ester compound include: “EXB9451”, “EXB9460”, “EXB9460S”, and “HPC-8000-65T” (manufactured by DIC Corporation) as active ester compounds including a dicyclopentadiene type diphenol structure; “EXB9416-70BK”, “EXB-8”, and “EXB-9425” (manufactured by DIC Corporation) as active ester compounds including an aromatic structure; “DC808” (manufactured by Mitsubishi Chemical Corporation) as an active ester compound including an acetylated product of phenol novolac; “YLH1026” (manufactured by Mitsubishi Chemical Corporation) as an active ester compound including a benzoylated product of phenol novolac; etc.

An ester equivalent (molecular weight/number of ester groups) of the active ester compound is not particularly limited. From the viewpoint of balancing various properties such as moldability, reflow resistance, electrical reliability, etc., a range of 150 g/eq to 400 g/eq is preferable, a range of 170 g/eq to 300 g/eq is more preferable, and a range of 200 g/eq to 250 g/eq is even more preferable.

The ester equivalent of the active ester compound is a value measured according to a method conforming to JIS K 0070:1992.

The curing agent may also include another curing agent other than the active ester compound. Examples of the another curing agent include phenol curing agents, amine curing agents, acid anhydride curing agents, polymercaptan curing agents, polyaminoamide curing agents, isocyanate curing agents, blocked isocyanate curing agents, etc. Specifically, phenol curing agents are preferable.

The resin composition for molding may include only one type of the another curing agent, or may include two or more types of the another curing agent.

### —Phenol Curing Agent—

Specific examples of the phenol curing agent include: polyvalent phenol compounds such as resorcinol, catechol, bisphenol A, bisphenol F, substituted or unsubstituted biphenols, etc.; novolac type phenol resins obtained by condensation or co-condensation, under acidic catalysis, of at least one phenolic compound selected from the group consisting of phenol compounds such as phenol, cresol, xylenol, resorcinol, catechol, bisphenol A, bisphenol F, phenylphenol, aminophenol, etc., and naphthol compounds such as α-naphthol, β-naphthol, dihydroxynaphthalene, etc., with aldehyde compounds such as formaldehyde, acetaldehyde, propionaldehyde, etc.; aralkyl type phenol resins such as phenol aralkyl resins, naphthol aralkyl resins, etc. synthesized from the above phenolic compounds with dimethoxy paraxylene, bis(methoxymethyl)biphenyl, etc.; paraxylylene-modified phenol resins, metaxylylene-modified phenol resins; melamine-modified phenol resins; terpene-modified phenol resins; dicyclopentadiene type phenol resins and dicyclopentadiene type naphthol resins synthesized by copolymerization of the above phenolic compounds with dicyclopentadiene; cyclopentadiene-modified phenol resins; polycyclic aromatic ring-modified phenol resins; biphenyl type phenol resins; triphenylmethane type phenol resins obtained by condensation or co-condensation, under acidic catalysis, of the above phenolic compounds with aromatic aldehyde compounds such as benzaldehyde, salicylaldehyde, etc.; phenol resins obtained by copolymerization of two or more of the above; etc. These phenol curing agents may be used as one type alone or used as a combination of two or more types.

A hydroxyl equivalent of the phenol curing agent is not particularly limited. From the viewpoint of balancing various properties such as moldability, reflow resistance, electrical reliability, etc., the hydroxyl equivalent of the phenol curing agent is preferably 70 g/eq to 1000 g/eq, and more preferably 80 g/eq to 500 g/eq.

The hydroxyl equivalent of the phenol curing agent is a value measured according to a method conforming to JIS K 0070:1992.

An equivalent ratio between the epoxy resin and the curing agent, i.e., a ratio (number of functional groups in the curing agent/number of functional groups in the epoxy resin) of the number of functional groups in the curing agent (preferably, the number of ester groups or the total number of ester groups and hydroxyl groups) to the number of functional groups in the epoxy resin (preferably, the number of epoxy groups), is not particularly limited. From the viewpoint of suppressing respective unreacted portions to lower levels, the equivalent ratio is preferably 0.5 to 2.0, and more preferably 0.6 to 1.3. From the viewpoint of moldability and reflow resistance, the equivalent ratio is even more preferably 0.8 to 1.2.

In the case where an active ester compound and a phenol curing agent are used in combination as the curing agent, a molar ratio (ester groups/phenol hydroxyl groups) of the ester groups included in the active ester compound to the phenol hydroxyl groups included in the phenol curing agent is preferably 9/1 to 1/9, more preferably 8/2 to 2/8, and even more preferably 3/7 to 7/3.

In the case where an active ester compound and another curing agent (preferably, a phenol curing agent) are used in combination as the curing agent, from the viewpoint of excellent flexural strength after curing the resin composition for molding and the viewpoint of suppressing the dielectric loss tangent of the cured product to a lower level, a mass ratio of the active ester compound in a total amount of the active ester compound and the another curing agent (preferably, a phenol curing agent) is preferably 40 mass % to 90 mass %, more preferably 50 mass % to 80 mass %, and even more preferably 55 mass % to 70 mass %.

Softening points or melting points of the active ester compound serving as the curing agent and the another curing agent such as a phenol curing agent used as necessary are not particularly limited. The softening point or the melting point of the curing agent is preferably 40° C. to 180° C. from the viewpoint of moldability and reflow resistance, and is more preferably 50° C. to 130° C. from the viewpoint of handling during manufacturing of the resin composition for molding.

The melting point or the softening point of the curing agent is a value measured in the same manner as the melting point or the softening point of the epoxy resin.

### (Inorganic Filler)

The resin composition for molding of the disclosure includes an inorganic filler. A type of the inorganic filler is not particularly limited. Specifically, examples thereof include inorganic materials such as fused silica, crystalline silica, glass, alumina, aluminum nitride, boron nitride, talc, clay, mica, titanium compounds such as calcium titanate, etc. Inorganic fillers with flame retardant effects may also be used. Examples of inorganic fillers with flame retardant effects include aluminum hydroxide, magnesium hydroxide, composite metal hydroxides such as composite hydroxides of magnesium and zinc, zinc borate, etc.

Among the inorganic fillers, silica such as fused silica is preferable from the viewpoint of reducing the coefficient of linear expansion, and alumina is preferable from the viewpoint of high thermal conductivity. Boron nitride is preferable from the viewpoint of further reducing the dielectric loss tangent. The inorganic filler may be used as one type alone or used as a combination of two or more types. Examples of a form of the inorganic filler include a powder, a bead formed by spheroidizing the powder, a fiber, etc.

An average particle diameter of the inorganic filler is not particularly limited. For example, a volume average particle diameter is preferably 0.2 μm to 50 μm, and more preferably 0.5 μm to 30 μm.

With the volume average particle diameter being 0.2 μm or more, there is a tendency that an increase in viscosity of the resin composition for molding is further suppressed. With the volume average particle diameter being 50 μm or less, there is a tendency that a filling property into narrow gaps is further improved. The volume average particle diameter of the inorganic filler refers to a value measured as a volume average particle diameter (D50) by a laser diffraction scattering particle size distribution analyzer.

The volume average particle diameter of the inorganic filler in the resin composition for molding or the cured product thereof may be measured according to a conventional method. As an example, the inorganic filler is extracted from the resin composition for molding or the cured product using organic solvents, nitric acid, aqua regia, etc., and is sufficiently dispersed using an ultrasonic disperser or the like to prepare a dispersion. Using this dispersion, the volume average particle diameter of the inorganic filler may be measured from a volume-based particle size distribution measured by a laser diffraction scattering particle size distribution analyzer. Alternatively, the volume average particle diameter of the inorganic filler may be measured from a volume-based particle size distribution obtained by embedding the cured product in a transparent epoxy resin or the like, performing polishing to obtain a cross-section, and observing the cross-section with a scanning electron microscope. Furthermore, the volume average particle diameter may also be measured by continuously observing two-dimensional cross-sections of the cured product to perform three-dimensional structure analysis using an FIB device (focused ion beam SEM) and the like.

From the viewpoint of flowability of the resin composition for molding, a particle shape of the inorganic filler is preferably a spherical shape, which is more preferable than an angular shape, and the particle size distribution of the inorganic filler is preferably a distribution in a wide range.

From the viewpoint of a low relative permittivity and a high fracture energy of the cured product, a content ratio of an entirety of the inorganic filler included in the resin composition for molding is preferably more than 40 volume %, more preferably more than 50 volume %, even more preferably more than 50 volume % and 80 volume % or less, and particularly preferably 55 volume % to 70 volume %, with respect to the entirety of the resin composition for molding.

The content ratio (volume %) of the inorganic filler in the resin composition for molding may be calculated according to the following method.

A thin slice sample of the cured product of the resin composition for molding is imaged using a scanning electron microscope (SEM). In the SEM image, any area S is specified, and a total area A of the inorganic filler included in the area S is calculated. A value obtained by dividing the total area A of the inorganic filler by the area S is converted to a percentage (%), and this value is taken as the content ratio (volume %) of the inorganic filler in the resin composition for molding.

The area S is an area sufficiently large compared to the size of the inorganic filler. For example, the area S is in a size in which 100 inorganic fillers or more are included. The area S may also be a sum of multiple cross-sections.

A bias for the inorganic filler may occur in a presence ratio in the gravity direction during curing of the resin composition for molding. In that case, when capturing images with the SEM, an entirety in the gravity direction of the cured product is imaged, and an area S in which the entirety in the gravity direction of the cured product is included is specified.

### (Porous Polymer Particle)

The resin composition for molding of the disclosure includes a porous polymer particle. By replacing a portion of the inorganic filler with the porous polymer particle, the relative permittivity can be lowered with the low dielectric loss tangent maintained.

The porous polymer particle is not particularly limited as long as the porous polymer particle is a porous particle including a polymer. The porous polymer particle preferably includes at least one polymer selected from the group consisting of (meth)acrylic polymers, olefin polymers, styrene polymers, and urethane polymers. From the viewpoint of easily reducing dimensional changes before and after curing of a molded product composed of the resin composition for molding, the porous polymer particle preferably includes a styrene polymer.

The porous polymer particle may include a core part having a porous structure and a shell part covering at least a part of the core part. With some pores located on a surface, the core part having a porous structure is formed with roughness on the surface. With the core part covered by the shell part, at least a part of the roughness is covered by the shell layer. Thus, the surface of the porous polymer particle tends to become smoother. As a result, it is inferred that flowability of the resin composition for molding is further improved.

A material of the core layer is not particularly limited, and examples thereof include (meth)acrylic polymers, olefin polymers, styrene polymers, urethane polymers, etc.

A material of the shell layer is not particularly limited, and examples thereof include (meth)acrylic resins, styrene resins, etc.

An average particle diameter of the porous polymer particle may be 1 μm to 15 μm, may be 3 μm to 12 μm, or may be 5 μm to 10 μm.

The average particle diameter of the porous polymer particle may be a value measured as a volume average particle diameter (D50) using a laser diffraction scattering particle size distribution analyzer, or may be an arithmetic mean of particle diameters of 100 randomly selected porous polymer particles observed in a cross-section of the composition, the cured product, etc. using a scanning electron microscope (SEM).

The porous polymer particle preferable has thermosetting properties. With the thermosetting properties included in the porous polymer, upon heating, since the porous polymer self-reacts and expands during heating, dimensional changes before and after curing of the molded product composed of the resin composition for molding become small. As a result, there is a tendency that warpage in an electronic component device including the cured product of the resin composition for molding can be reduced.

The porous polymer particle may be a hollow particle. In the case where the porous polymer particle is a hollow particle, from the viewpoint of balancing a low permittivity, kneadability, and flowability, a hollow rate of the porous polymer particle is preferably 30% to 70%, and more preferably 40% to 60%. For example, with the hollow rate of the porous polymer particle being 30% or more, there is a tendency that the permittivity of the cured product decreases. With the hollow rate of the porous polymer particle being 70% or less, there is a tendency that kneadability and flowability of the resin composition for molding are excellent.

The hollow rate may be measured according to the following method.

Upon observing the hollow particle using a transmission electron microscope, a solid portion and a hollow portion with different contrasts are observed. Lengths of the respective portions toward a center direction of the hollow particle are measured, and volumes are calculated from these values to calculate the hollow rate.

From the viewpoint of a low relative permittivity and a high fracture energy of the cured product, a content ratio of the porous polymer particle is preferably 5 volume % to 50 volume %, more preferably 8 volume % to 40 volume %, and even more preferably 10 volume % to 30 volume %, with respect to a total amount of the inorganic filler and the porous polymer particle.

From the viewpoint of a low dielectric loss tangent and a high fracture energy of the cured product, the content ratio of the porous polymer particle is preferably 3 volume % to 40 volume %, more preferably 5 volume % to 30 volume %, and even more preferably 8 volume % to 20 volume %, with respect to a total amount of the resin composition for molding.

### [Various Additives]

In addition to the components described above, the resin composition for molding of the disclosure may independently include, or may as well not include, each of various additives such as curing accelerators, coupling agents, ion exchangers, release agents, flame retardants, colorants, stress relief agents, etc., as exemplified below. The resin composition for molding of the disclosure may also include various conventional additives in the art as necessary, other than the additives exemplified below.

### (Curing Accelerator)

The resin composition for molding of the disclosure may include a curing accelerator. A type of the curing accelerator is not particularly limited and may be selected according to the type of the epoxy resin, desired properties of the resin composition for molding, etc. The curing accelerator may be used as one type alone or used as a combination of two or more types. Specific examples of the curing accelerator are described below, but are not limited thereto.

Examples of the curing accelerator include: diazabicycloalkenes such as 1,5-diazabicyclo[4.3.0]non-5-ene (DBN), 1,8-diazabicyclo[5.4.0]undec-7-ene (DBU), etc.; cyclic amidine compounds such as 2-methylimidazole, 2-phenylimidazole, 2-phenyl-4-methylimidazole, 2-heptadecylimidazole, etc.; derivatives of the above cyclic amidine compounds; phenol novolac salts of the above cyclic amidine compounds or derivatives thereof; compounds having intramolecular polarization formed by adding, to these compounds, compounds with π-bonds such as maleic anhydride, quinone compounds like 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, etc., and diazophenylmethane; cyclic amidinium compounds such as tetraphenylborate salt of DBU, tetraphenylborate salt of DBN, tetraphenylborate salt of 2-ethyl-4-methylimidazole, tetraphenylborate salt of N-methylmorpholine, etc.; tertiary amine compounds such as pyridine, triethylamine, triethylenediamine, benzyldimethylamine, triethanolamine, dimethylaminoethanol, tris(dimethylaminomethyl)phenol, etc.; derivatives of the above tertiary amine compounds; ammonium salt compounds such as tetra-n-butylammonium acetate, tetra-n-butylammonium phosphate, tetraethylammonium acetate, tetra-n-hexylammonium benzoate, tetrapropylammonium hydroxide, etc.; organic phosphines such as primary phosphines like ethylphosphine, phenylphosphine, etc., secondary phosphines like dimethylphosphine, diphenylphosphine, etc., tertiary phosphines like triphenylphosphine, diphenyl(p-tolyl)phosphine, tris(alkylphenyl)phosphine, tris(alkoxyphenyl)phosphine, tris(alkylalkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylalylphosphine, alkyldiarylphosphine, trinaphthylphosphine, tris(benzyl)phosphine, etc.; phosphine compounds such as complexes of the above organic phosphines with organoborons; compounds having intramolecular polarization formed by adding compounds with π-bonds such as maleic anhydride, quinone compounds like 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, anthraquinone, etc., and diazophenylmethane, with the above organic phosphines or the above phosphine compounds; compounds having intramolecular polarization obtained through a dehydrohalogenation process after reacting, with the above organic phosphines or the above phosphine compounds, halogenated phenol compounds such as 4-bromophenol, 3-bromophenol, 2-bromophenol, 4-chlorophenol, 3-chlorophenol, 2-chlorophenol, 4-iodinated phenol, 3-iodinated phenol, 2-iodinated phenol, 4-bromo-2-methylphenol, 4-bromo-3-methylphenol, 4-bromo-2,6-dimethylphenol, 4-bromo-3,5-dimethylphenol, 4-bromo-2,6-di-t-butylphenol, 4-chloro-1-naphthol, 1-bromo-2-naphthol, 6-bromo-2-naphthol, 4-bromo-4′-hydroxybiphenyl, etc.; tetrasubstituted phosphonium compounds such as tetrasubstituted phosphonium like tetraphenylphosphonium, tetraphenylborate salts of tetrasubstituted phosphonium like tetraphenylphosphonium tetra-p-tolylborate, salts of tetrasubstituted phosphonium with phenol compounds; phosphobetaine compounds; adducts of phosphonium compounds with silane compounds, etc.

Examples of suitable curing accelerators include triphenylphosphine, adducts of quinone compounds of triphenylphosphine, etc.

In the case where the resin composition for molding includes a curing accelerator, a content of the curing accelerator is preferably 0.1 parts by mass to 8 parts by mass, more preferably 0.3 parts by mass to 7 parts by mass, and even more preferably 0.5 parts by mass to 6 parts by mass, with respect to 100 parts by mass of a total amount of the epoxy resin and the curing agent. By configuring the content of the curing accelerator within the above numerical range, a curing rate of the resin composition for molding of the disclosure becomes an appropriate value, and manufacturing of the molded product becomes easy.

### (Coupling Agent)

The resin composition for molding of the disclosure may include a coupling agent. From the viewpoint of improving bonding of the inorganic filler with the epoxy resin and the curing agent, the resin composition for molding preferably includes a coupling agent. Examples of the coupling agent include conventional coupling agents such as silane-based compounds like epoxysilane, mercaptosilane, aminosilane, alkylsilane, ureidosilane, vinylsilane, disilazane, etc., titanium-based compounds, aluminum chelate-based compounds, aluminum/zirconium-based compounds, etc.

In the case where the resin composition for molding includes a coupling agent, an amount of the coupling agent is preferably 0.05 parts by mass to 5 parts by mass, and more preferably 0.1 parts by mass to 2.5 parts by mass, with respect to 100 parts by mass of the inorganic filler. With the amount of the coupling agent being 0.05 parts by mass or more with respect to 100 parts by mass of the inorganic filler, there is a tendency that bonding is further improved. With the amount of the coupling agent being 5 parts by mass or less with respect to 100 parts by mass of the inorganic filler, there is a tendency that moldability of a package is further improved.

### (Ion Exchanger)

The resin composition for molding of the disclosure may include an ion exchanger. From the viewpoint of improving moisture resistance and high-temperature storage properties of an electronic component device including a sealed electronic component, the resin composition for molding preferably includes an ion exchanger. The ion exchanger is not particularly limited, and conventional ion exchangers may be used. Specifically, examples thereof include hydrotalcite compounds, hydrous oxides of at least one element selected from the group consisting of magnesium, aluminum, titanium, zirconium, and bismuth, etc. The ion exchanger may be used as one type alone or used as a combination of two or more types. Specifically, hydrotalcite represented by General Formula (A) below is preferable.

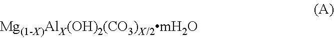

(0<X≤0.5, and m is a positive number)

In the case where the resin composition for molding includes an ion exchanger, a content thereof is not particularly limited as long as the amount is sufficient to capture ions such as halogen ions. For example, the content of the ion exchanger is preferably 0.1 parts by mass to 30 parts by mass, and more preferably 1 part by mass to 10 parts by mass, with respect to 100 parts by mass of a total of the epoxy resin and the curing agent.

### (Release Agent)

From the viewpoint of obtaining good releasability from the mold during molding, the resin composition for molding of the disclosure may include a release agent. The release agent is not particularly limited, and conventional release agents may be used. Specifically, examples thereof include higher fatty acids such as carnauba wax, montanic acid, stearic acid, etc.; metal salts of higher fatty acids; ester-based waxes such as montanic acid esters; polyolefin-based waxes such as oxidized polyethylene, non-oxidized polyethylene, etc. The release agent may be used as one type alone or used as a combination of two or more types.

In the case where the resin composition for molding includes a release agent, an amount thereof is preferably 0.01 parts by mass to 10 parts by mass, and more preferably 0.1 parts by mass to 5 parts by mass, with respect to 100 parts by mass of the resin component. With the amount of the release agent being 0.01 parts by mass or more with respect to 100 parts by mass of the resin component, there is a tendency that releasability is sufficiently obtained. With the amount of the release agent being 10 parts by mass or less with respect to 100 parts by mass of the resin component, there is a tendency that better bonding is obtained.

### (Flame Retardant)

The resin composition for molding of the disclosure may include a flame retardant. The flame retardant is not particularly limited, and conventional flame retardants may be used. Specifically, examples thereof include organic or inorganic compounds including halogen atoms, antimony atoms, nitrogen atoms, or phosphorus atoms, metal hydroxides, etc. The flame retardant may be used as one type alone or used as a combination of two or more types.

In the case where the resin composition for molding includes a flame retardant, an amount thereof is not particularly limited as long as the amount is sufficient to obtain a desired flame retardant effect. For example, the amount of the flame retardant is preferably 1 part by mass to 30 parts by mass, and more preferably 2 parts by mass to 20 parts by mass, with respect to 100 parts by mass of the total of the epoxy resin and the curing agent.

### (Colorant)

The resin composition for molding of the disclosure may include a colorant. Examples of the colorant include conventional colorants such as carbon black, organic dyes, organic pigments, titanium oxide, minimum, red iron oxide, etc. A content of the colorant may be appropriately selected according to the purpose and the like. The colorant may be used as one type alone or used as a combination of two or more types.

### (Stress Relief Agent)

The resin composition for molding of the disclosure may include a stress relief agent. By including a stress relief agent, occurrence of warpage deformation of a package and package cracking can be further reduced. Examples of the stress relief agent include conventional stress relief agents (flexible agents) generally used. Specifically, examples thereof include thermoplastic elastomers such as silicone-based, styrene-based, olefin-based, urethane-based, polyester-based, polyether-based, polyamide-based, polybutadiene-based thermoplastic elastomers, etc., indene-styrene-coumarone copolymers, organic phosphorus compounds such as triphenylphosphine oxide, phosphoric acid esters, etc., rubber particles such as natural rubber (NR), acrylonitrile-butadiene rubber (NBR), acrylic rubber, urethane rubber, silicone powder, etc., rubber particles having a core-shell structure such as methyl methacrylate-styrene-butadiene copolymer (MBS), methyl methacrylate-silicone copolymer, methyl methacrylate-butyl acrylate copolymer, etc. The stress relief agent may be used as one type alone or used as a combination of two or more types.

Examples of the silicone-based stress relief agent include silicone-based stress relief agents having an epoxy group, silicone-based stress relief agents having an amino group, silicone-based stress relief agents obtained by polyether-modifying the above, etc. Silicone compounds such as silicone compounds having an epoxy group, polyether-based silicone compounds, etc. are more preferable.

From the viewpoint of dielectric loss tangent, the stress relief agent preferably includes at least one of indene-styrene-coumarone copolymer and triphenylphosphine oxide.

In the case where the resin composition for molding includes a stress relief agent, an amount thereof is, for example, preferably 1 part by mass to 30 parts by mass, and more preferably 2 parts by mass to 20 parts by mass, with respect to 100 parts by mass of the total of the epoxy resin and the curing agent.

In the case where the stress relief agent includes at least one of indene-styrene-coumarone copolymer and triphenylphosphine oxide, the amount thereof is, for example, preferably 1 part by mass to 30 parts by mass, and more preferably 2 parts by mass to 20 parts by mass, with respect to 100 parts by mass of the total of the epoxy resin and the curing agent.

A content of the silicone-based stress relief agent may be, for example, 2 parts by mass or less, or may be 1 part by mass or less, with respect to 100 parts by mass of the total of the epoxy resin and the curing agent. It is also possible that the resin composition for molding does not include a silicone-based stress relief agent. A lower limit of the content of the silicone-based stress relief agent is not particularly limited, and may be 0 parts by mass, or may be 0.1 parts by mass.

From the viewpoint of dielectric loss tangent, a content ratio of the silicone-based stress relief agent is preferably 20 mass % or less, more preferably 10 mass % or less, even more preferably 7 mass % or less, particularly preferably 5 mass % or less, and most preferably 0.5 mass % or less, with respect to the entirety of the resin composition for molding. A lower limit of the content ratio of the silicone-based stress relief agent is not particularly limited, and may be 0 mass %, or may be 0.1 mass %.

### (Preparation Method of Resin Composition for Molding)

A preparation method of the resin composition for molding is not particularly limited. Examples of a general method may include a method in which components in predetermined formulation amounts are sufficiently mixed by a mixer or the like, and then are melt-kneaded by a mixing roll, an extruder, or the like, cooled, and pulverized. More specifically, examples may include a method in which predetermined amounts of the above components are stirred and mixed, kneaded by a kneader, a roll, an extruder, or the like preheated to 70° C. to 140° C., cooled, and pulverized.

The resin composition for molding of the disclosure is preferably a solid under normal temperature and pressure conditions (e.g., at 25° C. and atmospheric pressure). In the case where the resin composition for molding is a solid, a shape thereof is not particularly limited, and examples include forms of a powder, a granule, a tablet, etc. In the case where the resin composition for molding is in the form of a tablet, dimensions and a mass thereof are preferably configured to match molding conditions of the package, from the viewpoint of handling.

### (Applications of Resin Composition for Molding)

The resin composition for molding of the disclosure may be applied, for example, to manufacturing of electronic component devices to be described later, and among them, a high-frequency device in particular. The resin composition for molding of the disclosure may be used for sealing an electronic component in a high-frequency device.

In particular, in recent years, with the spread of the fifth-generation mobile communication system (5G), semiconductor packages (PKG) used in electronic component devices are becoming more advanced in functionality and smaller in size. Along with the miniaturization and functionality advancement of PKGs, development of an Antenna-in-Package (AiP), which is a PKG with an antenna function, is also progressing. In AiPs, to accommodate an increase in the number of channels due to diversification of information, radio waves used for communication are becoming higher in frequency, and sealing materials are required to have a low dielectric loss tangent.

As described above, the resin composition for molding of the disclosure yields a cured product with a low dielectric loss tangent. Thus, it is particularly suitable for Antenna-in-Package (AiP) applications, in which an antenna disposed on a supporting member is sealed with the resin composition for molding in high-frequency devices.

In an electronic component device including an antenna, such as an Antenna-in-Package, heat generation occurs due to power supply in the case where an amplifier for power supply is provided on the opposite side of the antenna. From the viewpoint of improving heat dissipation, the resin composition for molding used in manufacturing of the electronic component device preferably includes alumina particles as the inorganic filler.

### <Electronic Component Device>

The electronic component device of the disclosure includes a supporting member, an electronic component disposed on the supporting member, and a cured product of the above resin composition for molding that seals the electronic component.

Examples of the electronic component device include devices (e.g., high-frequency devices) obtained by mounting an electronic component (e.g., an active element such as a semiconductor chip, a transistor, a diode, a thyristor, etc.; a passive element such as a capacitor, a resistor, a coil, etc.; an antenna, etc.) on a supporting member such as a lead frame, a wired tape carrier, a wiring board, a glass, a silicon wafer, an organic substrate, etc., and sealing an obtained electronic component region with the resin composition for molding.

A type of the supporting member is not particularly limited, and supporting members generally used in manufacturing of electronic component devices may be used.

The electronic component may include an antenna, or may include an antenna and an element other than the antenna. The antenna is not particularly limited as long as it serves the role of an antenna, and may be an antenna element or a wiring.

Further, in the electronic component device of the disclosure, another electronic component may be disposed, as necessary, on a surface opposite to the surface on which the electronic component is disposed on the supporting member. The another electronic component may be sealed with the resin composition for molding, may be sealed with another resin composition, or may not be sealed.

### (Manufacturing Method of Electronic Component Device)

A manufacturing method of the electronic component device of the disclosure includes a process of disposing an electronic component on a supporting member, and a process of sealing the electronic component with the resin composition for molding described above.

Methods for implementing each of the above processes are not particularly limited, and may be performed according to general methods. Further, types of the supporting member and the electronic component used in manufacturing of the electronic component device are not particularly limited, and supporting members and electronic components generally used in manufacturing of electronic component devices may be used.

Examples of a method for sealing the electronic component using the resin composition for molding include low-pressure transfer molding, injection molding, compression molding, etc. Specifically, low-pressure transfer molding is a common method.

### EXAMPLES

Hereinafter, the embodiments will be specifically described based on Examples, but the scope of the embodiments is not limited to these Examples.

### <Preparation of Resin Composition for Molding>

Components shown below were mixed in formulation proportions (parts by mass) indicated in Table 1 to prepare resin compositions for molding of Examples and Comparative Examples. The resin composition for molding was a solid under normal temperature and pressure conditions.

In Table 1, “-” indicates that the component is not included.

Further, in Table 1, a “filler” refers to a total of the inorganic filler and the porous polymer.
Epoxy resin 1: Biphenyl type epoxy resin, epoxy equivalent 192 g/eq
Epoxy resin 2: Triphenylmethane type epoxy resin, epoxy equivalent 169 g/eq
Epoxy resin 3: o-Cresol novolac type epoxy resin, epoxy equivalent 200 g/eq
Curing agent: Active ester compound, DIC Corporation, product name “EXB-8”, ester equivalent 213 g/eq
Curing accelerator: Adduct of tributylphosphine and 1,4-benzoquinone
Coupling agent 1: 3-Glycidoxypropyltrimethoxysilane
Coupling agent 2: N-phenyl-3-aminopropyltrimethoxysilane
Colorant: Carbon black
Filler 1: Silica powder which is an inorganic filler, volume average particle diameter 0.5 μm, specific gravity 2.2 g/cm³
Filler 2: Silica powder which is an inorganic filler, volume average particle diameter 4.0 μm, specific gravity 2.2 g/cm³
Filler 3: Polymethyl methacrylate particle which is a porous polymer particle, volume average particle diameter 8 μm, maximum particle diameter 20 μm, spherical shape, thermal decomposition temperature 265° C., hollow rate 45%, specific gravity 0.6 g/cm³
Filler 4: Acrylic urethane polymer particle which is a porous polymer particle, volume average particle diameter 6 μm, spherical shape, thermal decomposition temperature 280° C., specific gravity 0.6 g/cm³
Filler 5: Styrene polymer particle which is a porous polymer particle including a shell layer (material: styrene resin), low oil absorption, volume average particle diameter 7 μm, maximum particle diameter 20 μm, spherical shape, thermal decomposition temperature 280° C., hollow rate 45%, specific gravity 0.6 g/cm³
Filler 6: Styrene polymer particle which is a porous polymer particle including a shell layer (material: styrene resin), low oil absorption, volume average particle diameter 7.5 μm, maximum particle diameter 20 μm, spherical shape, thermal decomposition temperature 290° C., hollow rate 50%, specific gravity 0.6 g/cm³

The volume average particle diameter of each of the inorganic fillers is a value obtained according to the following measurement.

Specifically, first, the inorganic filler was added to a dispersion medium (water) in a range of 0.01 mass % to 0.1 mass %, and dispersed for 5 minutes using a bath-type ultrasonic cleaner.

5 ml of the obtained dispersion was injected into a cell, and a particle size distribution was measured at 25° C. using a laser diffraction scattering particle size distribution analyzer (LA920, manufactured by HORIBA, Ltd.).

A particle diameter at a cumulative value of 50% (volume basis) in the obtained particle size distribution was taken as the volume average particle diameter.

### (Evaluation of Spiral Flow (SF))

Using a mold for measuring a spiral flow in accordance with EMMI-1-66, the resin composition for molding was molded by a transfer molding machine under conditions of a mold temperature of 175° C., a molding pressure of 6.9 MPa, and a curing time of 120 seconds, and a flow distance (cm) was calculated. The results are shown in Table 1.

### (Room Temperature Bending Test)

The resin composition for molding was loaded into a transfer molding machine and molded under conditions of a mold temperature of 175° C., a molding pressure of 6.9 MPa, and a curing time of 120 seconds, and a post-curing was performed under conditions of 175° C. and 6 hours to prepare a rectangular parallelepiped test piece of 127 mm×12.7 mm×4 mm.

Using Tensilon (A&D Co., Ltd.) as an evaluation apparatus, a three-point support bending test in accordance with JIS-K-7171 (2016) was performed at room temperature (25° C.), and a flexural modulus E, a flexural strength S, and an elongation at break F of the test piece were calculated according to the following equations.

The flexural modulus E (GPa), the flexural strength S (MPa), and the elongation at break ε (%) are defined by the following equations.

In the following equations, P is a load cell value (N), y is a displacement (mm), l is a span=64 mm, w is a test piece width=12.7 mm, and h is a test piece thickness=4 mm. A subscript max indicates a maximum value. The flexural modulus E was obtained by converting a value calculated according to the equation described below to GPa.

$$E = \frac{{l}^{3}}{4 {wh}^{3}} \frac{Δ P}{Δ y} \qquad [ Math . 1 ]$$

$$S = \frac{3 l}{2 {wh}^{2}} {P}_{max} \qquad [ Math . 2 ]$$

$$ε = \frac{6 h}{{l}^{2}} {y}_{max} \qquad [ Math . 3 ]$$

### (Measurement of Fracture Energy)

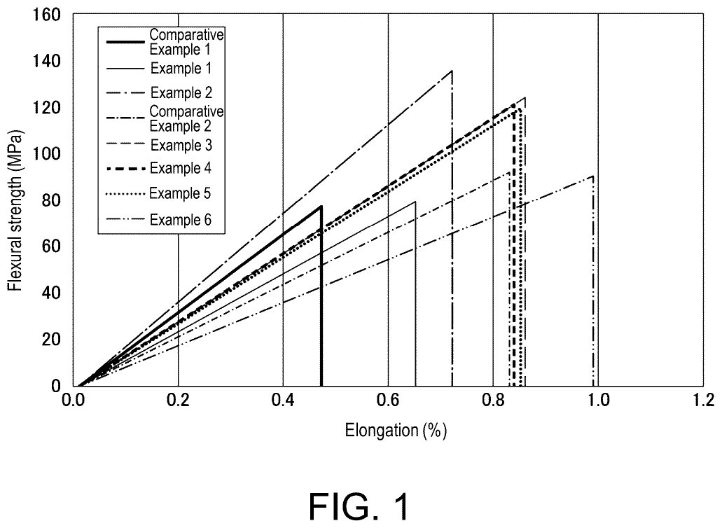

Regarding the resin composition for molding, the above bending test was performed, an area of an S-S curve of the elongation at break (%) and the flexural strength (MPa) was calculated according to the following equation, and this value was taken as a fracture energy. FIG. 1 shows an S-S curve of an elongation at break and a flexural strength obtained using the resin composition for molding of each Example and each Comparative Example.

The results are shown in Table 1.

$$Fracture energy = {\int }_{{ε}_{Min}}^{{ε}_{Max}} ( {σ}_{Min} + {σ}_{Max} ) d σ \qquad [ Math . 4 ]$$

$$\begin{matrix}σ = flexural strength & ε =\end{matrix} elongation at break$$

### (Measurement of Molding Shrinkage)

The resin composition for molding was molded using a transfer molding machine under conditions of a molding temperature of 175° C., a molding pressure of 6.9 MPa, and a curing time of 120 seconds to obtain a plate-shaped molded product (127 mm in length, 12.7 mm in width, and 6.4 mm in thickness).

A molding shrinkage A (%) (molding shrinkage AM in Table 1) was calculated according to the following equation based on a length D of a cavity of the mold at 25° C. measured in advance and a length d of the molded product at room temperature (25° C.). The results are shown in Table 1.

$$Molding shrinkage A ( \% ) = ( ( D - d ) / D ) \times 100$$

The resin composition for molding was molded using a transfer molding machine under conditions of a molding temperature of 175° C., a molding pressure of 6.9 MPa, and a curing time of 120 seconds to obtain a plate-shaped molded product (127 mm in length, 12.7 mm in width, and 6.4 mm in thickness). Post-curing was performed on the molded product at 175° C. for 5 hours to obtain a plate-shaped cured product.

A molding shrinkage B (%) (molding shrinkage AC in Table 1) was calculated according to the following equation based on a length D of a cavity of the mold at 25° C. measured in advance and a length d of the cured product at room temperature (25° C.). The results are shown in Table 1.

$$Molding shrinkage B ( \% ) = ( ( D - d ) / D ) \times 100$$

### (Measurement of Relative Permittivity and Dielectric Loss Tangent)

The resin composition for sealing was loaded into a transfer molding machine and molded under conditions of a mold temperature of 180° C., a molding pressure of 6.9 MPa, and a curing time of 90 seconds, and a post-curing was performed at 175° C. for 6 hours to obtain a rod-shaped cured product (90 mm in length, 0.6 mm in width, and 0.8 mm in thickness). Taking this cured product as a test piece, a relative permittivity (Dk) and a dielectric loss tangent (Df) at 10 GHz were measured at a temperature of 25±3° C. using a cavity resonator (Kanto Electronic Application & Development Co., Ltd.) and a network analyzer (Keysight Technologies, model name “PNA E8364B”).

The model of the cavity resonator used is as follows:
10 GHz . . . CP531

TABLE 1

| | | Comparative | Example | Example | Comparative | Example | Example | Example | Example |
|---|---|---|---|---|---|---|---|---|---|
| | | Example 1 | 1 | 2 | Example 2 | 3 | 4 | 5 | 6 |
| Epoxy resin 1 | | 25 | 25 | 25 | 25 | 25 | 25 | 25 | 25 |
| Epoxy resin 2 | | 75 | 75 | 75 | | | | | |
| Epoxy resin 3 | | | | | 75 | 75 | 75 | 75 | 75 |
| Curing agent | | 122 | 122 | 122 | 108 | 108 | 108 | 108 | 108 |
| Curing accelerator | | 3.5 | 3.5 | 3.5 | 3.5 | 3.5 | 3.5 | 3.5 | 3.5 |
| Coupling agent 1 | | 6 | 6 | 6 | | | | | |
| Coupling agent 2 | | | | | 6 | 6 | 6 | 6 | 6 |
| Colorant | | 2.5 | 2.5 | 2.5 | 2.5 | 2.5 | 2.5 | 2.5 | 2.5 |
| Filler 1 | | 163 | 132 | 132 | 213 | 213 | 213 | 212 | 213 |
| Filler 2 | | 653 | 526 | 526 | 851 | 691 | 691 | 637 | 426 |
| Filler 3 | | | 45 | | | | | | |
| Filler 4 | | | | 45 | | | | | |
| Filler 5 | | | | | | | 43 | 58 | 116 |
| Filler 6 | | | | | | 43 | | | |
| Total | | 1050.3 | 936.5 | 936.5 | 1284 | 1167 | 1167 | 1127 | 975 |
| Resin volume | | 200 | 200 | 200 | 188 | 188 | 188 | 188 | 188 |
| Porous polymer volume | | 0 | 75 | 75 | 0 | 72 | 72 | 97 | 193 |
| Inorganic filler volume | | 371 | 299 | 299 | 484 | 411 | 411 | 386 | 290 |
| Filler total/entirety | | 65 | 65 | 65 | 72 | 72 | 72 | 72 | 72 |
| (volume ratio) | | | | | | | | | |
| Silica/entirety | | 65 | 52 | 52 | 72 | 61 | 61 | 58 | 43 |
| (volume ratio) | | | | | | | | | |
| Porous polymer/entirety | | 0 | 13 | 13 | 0 | 11 | 11 | 14 | 29 |
| (volume ratio) | | | | | | | | | |
| Porous polymer/filler | | 0 | 20 | 20 | 0 | 15 | 15 | 20 | 40 |
| (volume ratio) | | | | | | | | | |
| Silica/filler | | 100 | 80 | 80 | 100 | 85 | 85 | 80 | 60 |
| (volume ratio) | | | | | | | | | |
| Fracture energy | | 17.9 | 25.7 | 38.6 | 49.1 | 52.8 | 50.8 | 51.1 | 45.0 |
| Molding | Molding | 0.52 | 0.66 | 0.69 | 0.31 | 0.27 | 0.27 | 0.27 | 0.31 |
| shrinkage | shrinkage AM | | | | | | | | |
| | Molding | 0.46 | 0.48 | 0.44 | 0.31 | 0.28 | 0.27 | 0.26 | 0.21 |
| | shrinkage AC | | | | | | | | |
| Dk (10 GHz) | | 3.32 | 3.19 | 3.21 | 3.35 | 3.18 | 3.20 | 3.12 | 2.89 |
| Df (10 GHz) | | 0.0035 | 0.0035 | 0.0038 | 0.0025 | 0.0023 | 0.0026 | 0.0024 | 0.0031 |
| Flow- | SF | 145 | 70 | 68 | 142 | 140 | 146 | 113 | 80 |
| ability | | | | | | | | | |
| Bending | Flexural | 77 | 79 | 92 | 135 | 124 | 121 | 119 | 89 |
| test | strength (MPa) | | | | | | | | |
| | Flexural | 16.1 | 12.4 | 11.9 | 22.1 | 17.0 | 17.7 | 15.8 | 10.2 |
| | modulus (GPa) | | | | | | | | |
| | Elongation | 0.47 | 0.65 | 0.83 | 0.72 | 0.86 | 0.84 | 0.85 | 0.99 |
| | at break (%) | | | | | | | | |

As is clear from the evaluation results in Table 1, the cured products of the resin compositions for molding in Example 1 and Example 2 exhibited a lower relative permittivity than the cured product of the resin composition for molding in Comparative Example 1, which used the same type of epoxy resin.

The cured products of the resin compositions for molding in Example 3 to Example 6 exhibited a lower relative permittivity than the cured product of the resin composition for molding in Comparative Example 2, which used the same type of epoxy resin. Furthermore, in Example 4 to Example 6, a tendency has been confirmed, in which the molding shrinkage after curing decreases as the amount of the filler 5, which is a porous polymer particle, increases.

### (Confirmation of Viscoelastic Property Changes Due to Heating)

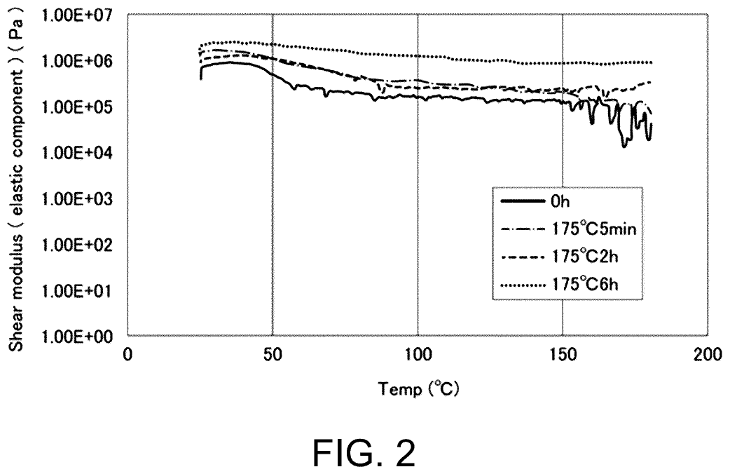

Viscoelastic measurements were performed on the filler 5 in states of being unheated (0h), after heating at 175° C. for 5 minutes, 2 hours, or 6 hours. For the viscoelastic measurements, test samples in states of being unheated (0h) and after heating at 175° C. for 5 minutes, 2 hours, or 6 hours were prepared. Measurements were performed using a rotational rheometer Kinexus lab+(manufactured by NETZSCH Japan Co., Ltd.) under conditions of: amplitude method, Strain=0.1%, frequency=1 Hz, GAP=0.5 mm, measurement temperature range 25° C. to 180° C., and heating rate 10° C./min. The results are shown in FIG. 2. In FIG. 2, 1.00E+0X (where X is an integer) represents 10^{X} (10 to the power of X).

As shown in FIG. 2, the samples obtained by heating the composition exhibited a high elastic modulus at the measurement temperature. Based on this result, it is inferred that the filler 5 exhibited self-reactivity (i.e., thermosetting property) due to heating.

The disclosure of Japan Patent Application No. 2022-188706, filed on Nov. 25, 2022, is incorporated in its entirety herein by reference.

All literatures, patent applications, and technical standards described in this specification are incorporated herein by reference to the same extent as the case where each literature, patent application, and technical standard is specifically and individually indicated to be incorporated by reference.

1. A resin composition for molding comprising: an epoxy resin, a curing agent containing an active ester compound, an inorganic filler, and a porous polymer particle.

2. The resin composition for molding according to claim 1, wherein the porous polymer particle comprises a core part having a porous structure and a shell part covering at least a part of the core part.

3. The resin composition for molding according to claim 1, wherein the porous polymer particle comprises a core part having a porous structure, and the core part comprises at least one polymer selected from a group consisting of (meth)acrylic polymers, olefin polymers, styrene polymers, and urethane polymers.

4. The resin composition for molding according to claim 1, wherein a content ratio of the porous polymer particle is 5 volume % to 50 volume % with respect to a total amount of the inorganic filler and the porous polymer particle.

5. The resin composition for molding according to claim 1, wherein a content ratio of the porous polymer particle is 3 volume % to 40 volume % with respect to a total amount of the resin composition for molding.

6. The resin composition for molding according to claim 1, wherein the porous polymer particle has thermosetting properties.

7. The resin composition for molding according to claim 1, which is used for a high-frequency device.

8. The resin composition for molding according to claim 7, which is used for sealing an electronic component in the high-frequency device.

9. The resin composition for molding according to claim 7, which is used for an Antenna-in-Package.

10. An electronic component device comprising:
a supporting member;
an electronic component disposed on the supporting member; and
a cured product of the resin composition for molding according to claim 1, which seals the electronic component.

11. The electronic component device according to claim 10, wherein the electronic component comprises an antenna.
